(19) United States
(12) Patent Application Publication
(10) Pub. No.: US 2016/0224141 A1
(43) Pub. Date: Aug. 4, 2016

(54) ELECTRONIC DEVICE, METHOD OF MANUFACTURING SAME AND DISPLAY DEVICE

(71) Applicant: GIO Optoelectronics Corp., Tainan City (TW)

(72) Inventor: Yuan-Liang WU, Tainan City (TW)

(21) Appl. No.: 15/010,761

(22) Filed: Jan. 29, 2016

(30) Foreign Application Priority Data
Jan. 30, 2015 (TW) 104103294

(51) Int. Cl. G06F 3/041; H05K 3/14; H05K 3/16

(52) U.S. Cl. CPC G06F 3/041; H05K 3/16; H05K 3/143; G06F 2203/04103

(57) ABSTRACT

An electronic device with an active area is disclosed. The electronic device includes a substrate and a first pattern circuit layer. The first pattern circuit layer is disposed at one side of the substrate. The first pattern circuit layer has at least one metal net structure. In the active area, the metal net structure has a first thickness and a second thickness. The second thickness is thinner than the first thickness. An electronic manufacturing method is also disclosed. The electronic device made by the manufacturing method can simplify the manufacturing processes.

### CROSS REFERENCE TO RELATED APPLICATIONS

This Non-provisional application claims priority under 35 U.S.C. §119(a) on Patent Application No(s). 104103294 filed in Taiwan, Republic of China on Jan. 30, 2015, the entire contents of which are hereby incorporated by reference.

### BACKGROUND

1. Technical Field

The invention relates to an electronic device, in particular to an electronic device, a method of manufacturing electronic device and the display device applied with such electronic device.

2. Related Art

As technology develops, various advanced information devices for example mobile phone, tablet computer, ultrabook computer, GPS navigator, etc. are produced. In addition to a general keypad or a mouse for input or manipulation, using information device by touch pad is a friendly and popular manipulation manner. The popular touch device has friendly and straight input interface, so it is easy for any age user to directly manipulate the information device with his finger or touch pen.

Generally, touch panels for touch device can be classified into resistive touch panel, capacitive touch panel, and optics touch panel by their sensing manners. Currently, the capacitive touch panel of high sensitivity and multi-touch is one of main techniques. Because the capacitive touch panel can detect multi-touch, it is adapted for the electronic device with high precision for frequent use, for example, smart phone, tablet computer or notebook computer with touch-input interface.

The capacitive touch panel usually utilizes transparent conductive thin film (e.g. ITO). Its operation is based on capacitive coupling between the transparent conductive thin film on the touch panel and the human finger due to touch. After processing of control unit, coordination data for operation system is accordingly generated to determine the touch position. In traditional touch panels, a plurality of transparent electrodes (or called conductive patterns) need forming on the glass substrate by lithography process.

However, lithography process is complicated. It applies photoresist first, and then exposure is performed with a mask which contains patterns like previously mentioned arranged transparent electrodes. After development, etching, cleaning, etc., arranged transparent electrodes are formed. Thus, such complicated lithography process causes high manufacturing cost. For most capacitive touch panels, insulation material needs disposed at the intersection of the transparent electrodes to avoid short circuit, so such panels need more complicated manufacturing process.

However, in addition to touch panel, lithography process is still utilized to produce the designate pattern or circuit in many electronic devices. In addition to complicated manufacturing process, the transparent conductive thin film also requires high product cost.

### SUMMARY

One aspect of the disclosure is to provide an electronic device, a method of manufacturing electronic device, and a display device applied with such electronic device. The method of manufacturing such electronic device is simplified.

One aspect of the disclosure is to provide an electronic device of high transmittance and low cost.

In one embodiment, an electronic device comprises a substrate and a first patterned circuit layer. The first patterned circuit layer is disposed at one side of the substrate. The linewidth of at least one part of the first patterned circuit layer is between 0.1˜100 μm. The at least one part of the first patterned circuit layer has a first thickness and a second thickness, and the second thickness is smaller than the first thickness.

In one embodiment, the electronic device includes an active area where the first patterned circuit layer has the first thickness and the second thickness.

In one embodiment, the active area is a radiation area of an antenna, a visible area of a display panel, or a detection area of a touch panel.

In one embodiment, the first patterned circuit layer includes a grid structure.

In one embodiment, the first patterned circuit layer further comprises a plurality of first conductive units, at least one of the first conductive units includes the first metal grid structure, and the first metal grid structure includes a plurality of first conductive portions and a plurality of second conductive portions. At least one of the first conductive portions is connected to the adjacent second conductive portions, the thickness of the at least one of the first conductive portions is denoted by the first thickness, and the thickness of the at least one of the second conductive portions is denoted by the second thickness.

In one embodiment, the first conductive units are arranged in an array.

In one embodiment, the first patterned circuit layer further comprises a plurality of second conductive units. At least one of the second conductive units comprises another first metal grid structure. The first conductive units are arranged along a first axis direction in sequence, and the second conductive units are arranged along a second axis direction in sequence.

In one embodiment, each of the first conductive units includes at least one first electrical connection member to be electrically connected to the adjacent first conductive unit. Each of the second conductive units includes at least one second electrical connection member to be electrically connected to the adjacent second conductive unit, and the first electrical connection member of the first conductive unit crisscrosses the second electrical connection member of the adjacent second conductive unit.

In one embodiment, the electronic device further comprises an insulation layer. The insulation layer comprises a plurality of insulation members respectively disposed between the first electrical connection member of each of the first conductive units and the second electrical connection member of each of the second conductive units to electrically isolate the first conductive units from the second conductive units.

In one embodiment, the electronic device further comprises an insulation layer and a second patterned circuit layer. The first patterned circuit layer is disposed on the insulation layer. The insulation layer is disposed on the second patterned circuit layer. The second patterned circuit layer comprises at least one second metal grid structure. Within the active area, the second metal grid structure has a third thickness and a fourth thickness, and the fourth thickness is smaller than the third thickness.

In one embodiment, the electronic device the first patterned circuit layer further comprises a plurality of first conductive units. The second patterned circuit layer further comprises a plurality of second conductive units. At least one of the second conductive units comprises the second metal grid structure. The second metal grid structure includes a plurality of third conductive portions and a plurality of the fourth conductive portions. At least one of the third conductive portions is connected to the adjacent fourth conductive portions. The thickness of the at least one of the third conductive portions is denoted by the third thickness, and the thickness of the at least one of the fourth conductive portions is denoted by the fourth thickness.

In one embodiment, a method of manufacturing an electronic device comprises: providing a substrate; and depositing at least one first patterned circuit layer at one side of the substrate by a first mask. The linewidth of at least one part of the first patterned circuit layer is between 0.1˜100 μm, the at least one part of the first patterned circuit layer has a first thickness and a second thickness, and the second thickness is smaller than the first thickness.

In one embodiment, the at least one first patterned circuit layer is deposited by sputtering.

In one embodiment, the electronic device includes an active area, and the at least one first patterned circuit layer is deposited by the first mask within the active area.

In one embodiment, the method further comprises: forming a second patterned circuit layer by a second mask, wherein the second patterned circuit layer has a third thickness and a fourth thickness, and the fourth thickness is smaller than the third thickness; and forming an insulation layer on the second patterned circuit layer, wherein the first patterned circuit layer is formed on the insulation layer.

In one embodiment, the electronic device includes an active area, and the second patterned circuit layer is deposited by the second mask within the active area.

In one embodiment, a display device comprises: a first substrate, a second substrate, a display medium and a first patterned circuit layer. The second substrate is disposed opposite the first substrate and includes an active area. The display medium is disposed between the first substrate and the second substrate. The first patterned circuit layer is disposed at one side of the second substrate. The first patterned circuit layer includes at least one first metal grid structure. Within the active area, the first metal grid structure has a first thickness and a second thickness, and the second thickness is smaller than the first thickness.

In one embodiment, the first patterned circuit layer is disposed at one side of the second substrate facing the display medium.

In one embodiment, the first patterned circuit layer is disposed at one side of the second substrate away from the first substrate.

In one embodiment, the display device further comprises an insulation layer and a second patterned circuit layer. The first patterned circuit layer is disposed on the insulation layer, the insulation layer is disposed on the second patterned circuit layer. The second patterned circuit layer comprises at least one second metal grid structure. Within the active area, the second metal grid structure has a third thickness and a fourth thickness, and the fourth thickness is smaller than the third thickness.

In summary, the patterned circuit layer is disposed on the substrate by depositing with mask. This manufacturing process is simple and can replace lithography process of multiple steps so as to decrease the manufacturing steps. In the embodiment, metal grid structures have similar transmittance to the conventional transparent circuit, and the designate material of transparent metal oxide is not required. The overall required amount of metal and cost can be reduced.

### BRIEF DESCRIPTION OF THE DRAWINGS

The embodiments will become more fully understood from the detailed description and accompanying drawings, which are given for illustration only, and thus are not limitative of the present invention, and wherein:

FIG. 1A is a schematic diagram of an electronic device according to a first embodiment;

FIG. 1B is a partial enlarged diagram of the mask for manufacturing the device in FIG. 1A;

FIG. 1C is a schematic diagram showing the mask and the patterned circuit layer of the electronic device in FIG. 1 in manufacturing process;

FIG. 2A is a schematic diagram of an electronic device according to an embodiment;

FIG. 2B is a schematic diagram of an electronic device according to an embodiment;

FIG. 2C is a schematic diagram of an electronic device according to an embodiment;

FIG. 3A is a schematic diagram of an electronic device according to a second embodiment;

FIG. 3B is a partial enlarged diagram of FIG. 3A;

FIG. 4A is a partial enlarged diagram of the mask for manufacturing the device in FIG. 3A;

FIG. 4B is a schematic diagram showing the mask and the patterned circuit layer of the electronic device in FIG. 3A in manufacturing process;

FIG. 5 is a flow chart showing the steps of the method of manufacturing electronic device;

FIG. 6 is a partial enlarged diagram of another mask for manufacturing electronic device;

FIG. 7A is a partial enlarged diagram of another mask for manufacturing electronic device;

FIG. 7B is a perspective diagram of the mask in FIG. 7A;

FIG. 8 is a partial enlarged diagram of another mask for manufacturing electronic device;

FIG. 9 is a schematic diagram of an electronic device according to a third embodiment;

FIG. 10A is a partial enlarged diagram of FIG. 9;

FIG. 10B is a partial enlarged diagram of the mask for manufacturing the device in FIG. 9;

FIG. 11A is a schematic diagram of the second patterned circuit layer of the electronic device in FIG. 9;

FIG. 11B is a schematic diagram showing the mask and the patterned circuit layer in manufacturing process of the electronic device in FIG. 9;

FIG. 11C is a schematic diagram showing the variation of the mask for manufacturing electronic device and patterned circuit layer in FIG. 9;

FIG. 11D is a flow chart showing the steps of the manufacturing method electronic device according to the third embodiment;

FIG. 12 is a schematic diagram showing the intermediate structure in the manufacturing process of the electronic device according to the third embodiment; and

FIG. 13 is a schematic diagram of the patterned circuit layer of the electronic device according to the third embodiment.

### DETAILED DESCRIPTION OF THE INVENTION

The embodiments of the invention will be apparent from the following detailed description, which proceeds with reference to the accompanying drawings, wherein the same references relate to the same elements.

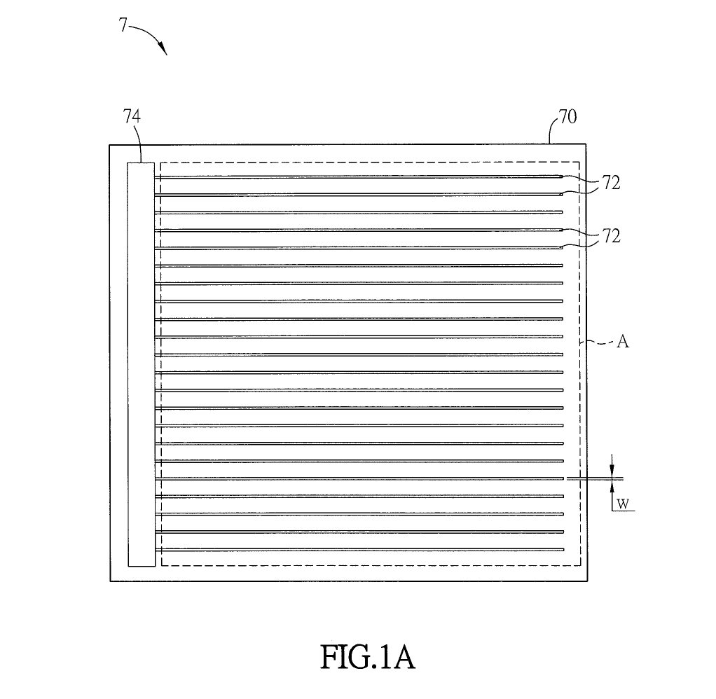

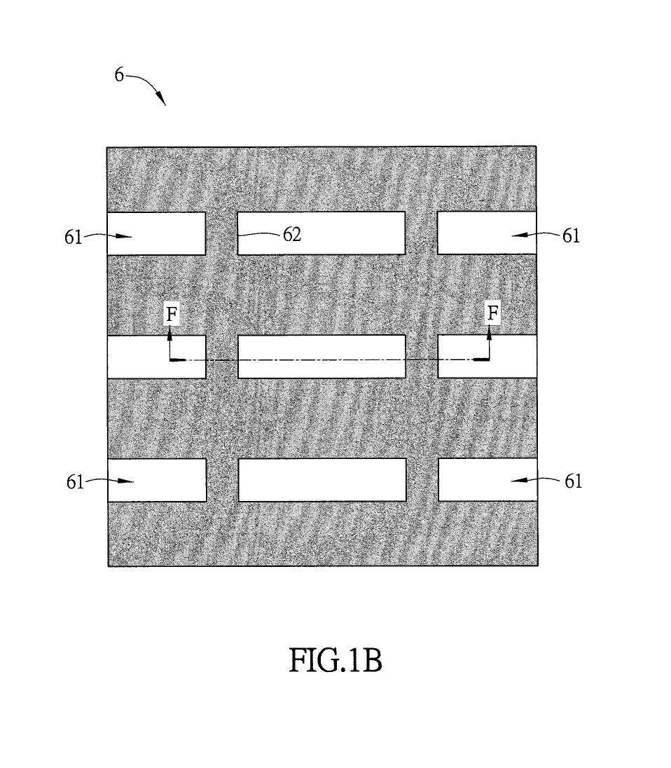

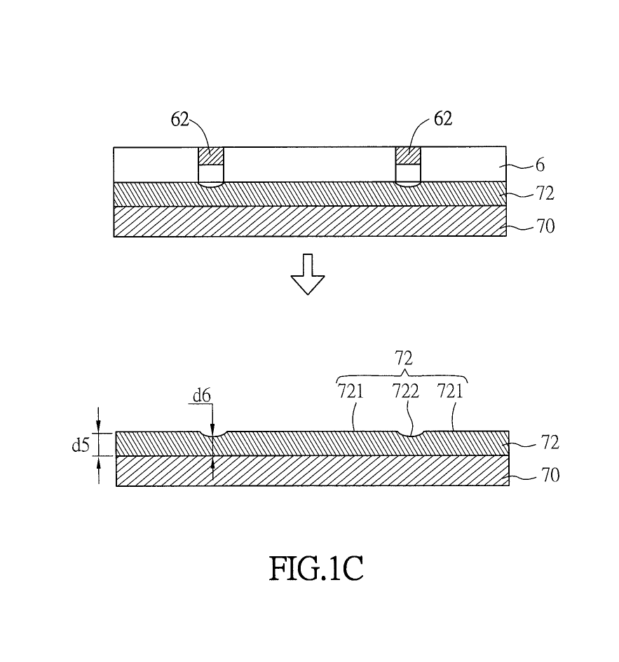

In an electronic device according to a first embodiment, a patterned circuit layer which is a single layer is disposed on the substrate. Following description is illustrated with FIG. 1A.

FIG. 1A is a schematic diagram of an electronic device according to the first embodiment. The electronic device 7 comprises a substrate 70 and a first patterned circuit layer 72. The substrate 70 varies depending on demand. In the embodiment, the substrate 70 is a transparent the substrate, and it may be a rigid substrate or a flexible substrate. The material of the substrate includes glass, quartz, sapphire, macromolecule material, resin material, etc. In the embodiment, it is a glass substrate for example.

The first patterned circuit layer 72 is disposed at one side of the substrate 70. The first patterned circuit layer 72 can have any shapes or it can be patterned with any shapes. In the embodiment, there are a plurality of parallel circuit structures in the same patterned circuit layer which is a single circuit layer formed by the same mask for example. Namely, the embodiment may be applied to any single circuit layer on the substrate for example the copper trace layer on PCB. In the embodiment, the first patterned circuit layer 72 is disposed on a surface of the substrate 70 for example. The first patterned circuit layer has a linewidth w of which the dimension may be between 0.1˜100 μm. In the embodiment, the electronic device 7 includes an active area A where the patterned circuit layer is disposed, but the dimension and location of the active area is not specifically limited. In the embodiment, the electronic device 7 is a TFT substrate of a display panel for example. The data lines of the TFT substrate may be formed by the similar method for the first patterned circuit layer 72. The display panel may be an LCD panel or a display panel which includes a micro LED array consisted of μLEDs (micro LED). The dimension of the μLED is about 1/30˜ 1/10 of the dimension of the traditional LED.

Then, referring to FIG. 1B and FIG. 1C, FIG. 1B is a partial enlarged top view of the mask for manufacturing the device in FIG. 1A. Referring to FIG. 1B, the mask 6 includes a plurality of hollow portions 61. The connection portions 62 are located between the hollow portions 61 to enhance the mechanical strength of the mask 6 at the hollow portions 61 in the direction of the major axis. Moreover, there may be a plurality of the connection portions 62 between the adjacent the hollow portions 61, but in the embodiment, just a single connection portion 62 between the adjacent the hollow portions 61 is illustrated for example.

FIG. 1C shows the first patterned circuit layer 72 along the sectional line FF in FIG. 1B. The first patterned circuit layer 72 may further comprise a plurality of first conductive portions 721 and a plurality of second conductive portions 722. Because the first conductive portions 721 and the second conductive portions 722 are formed by the same mask, the material of the first conductive portion 721 is the same with the material of the second conductive portion 722. However, the thicknesses of the first conductive portion 721 and the second conductive portion 722 are not equal, and the unequal reason will be descripted later. The second conductive portion 722 is connected to the adjacent first conductive portions 721 to form the first patterned circuit layer 72 in FIG. 1A. The thickness of the first conductive portion 721 is denoted by the first thickness d5, and the thickness of the second conductive portion 722 is denoted by the second thickness d6. The second thickness d6 is smaller than the first thickness d5. Even the difference between the second thickness d6 and the first thickness d5 is greater than 5%, the electrical conduction of the first patterned circuit layer 72 is still not impacted. By designing the dimension and location of the connection portion 62 of the mask 6, the difference between the first thickness d5 and the second thickness d6 is adjusted. For example, increasing the density of the second conductive portion 722 results in that the first patterned circuit layer 72 has more uniform thickness and better conductibility.

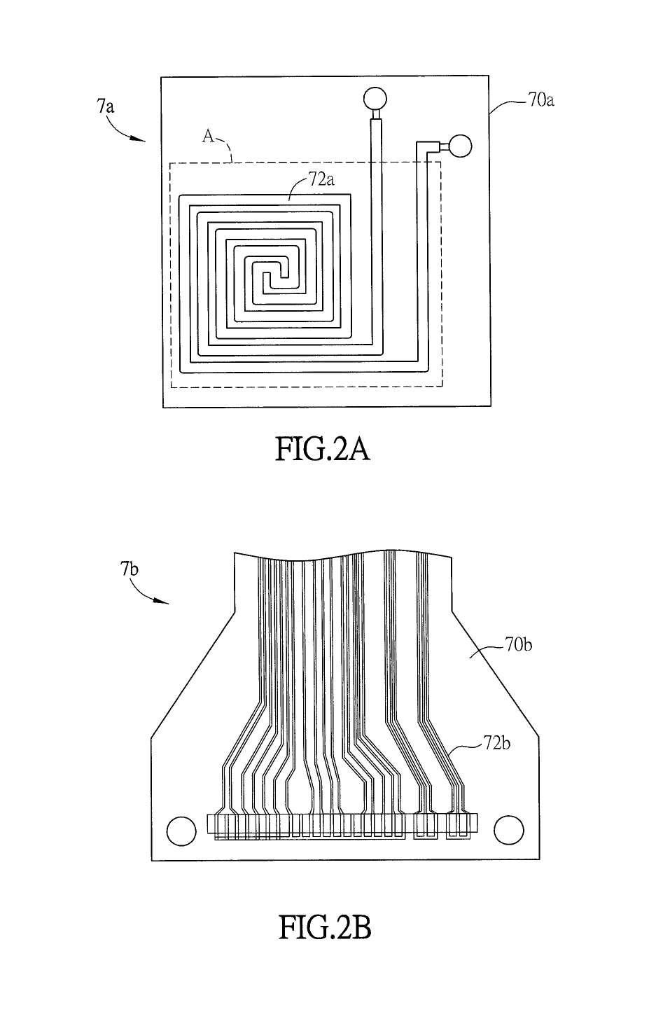

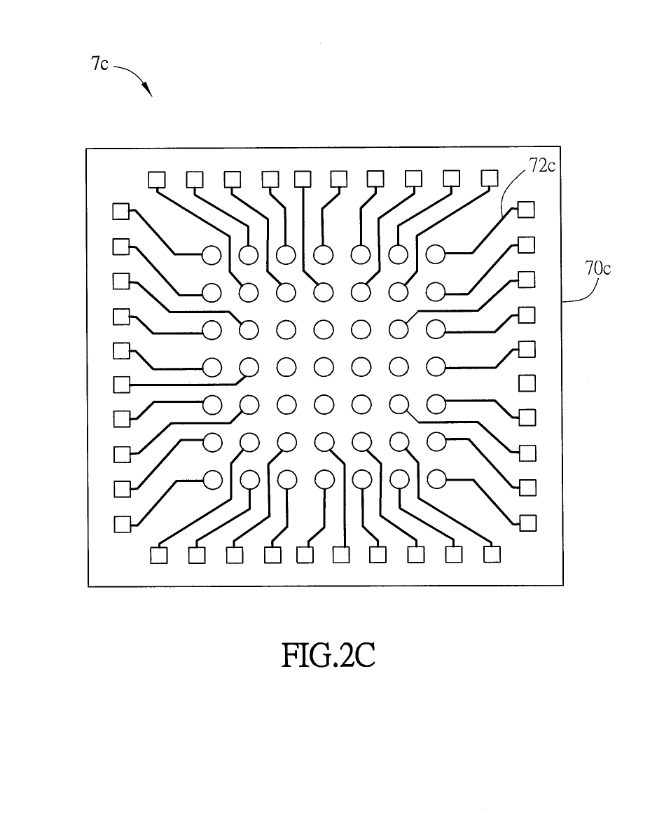

FIG. 1B is a partial enlarged diagram of the mask 6 for manufacturing the first patterned circuit layer 72. In the embodiment, the mask 6 comprises a plurality of the hollow portions 61 and connection portions 62. The connection portions 62 act as ribs for enhancing the structure strength of the mask 6, and help using the mask 6. The material of the mask 6 is for example but not limited to Ni—Fe alloy and it can be a multiple layer structure. Referring to FIG. 1C, in the manufacturing process, the mask 6 may be disposed very close to the substrate 70. The thickness of the connection portions 62 may be different from the thickness of the mask 6. In FIG. 1C, the thickness of the connection portion 62 is smaller than the thickness of the mask 6, and even it is half of the thickness of the mask 6. Conductive material for sputtering may be deposited on the substrate 70 by the mask 6, so the first patterned circuit layer 72 is formed on the substrate 70. Because the connection portions 62 block the deposition of the conductive material, the thicker first conductive portion 721 is formed at the place corresponding to the hollow portion 61 of the mask 6. When the conductive material is deposited from the hollow portion 61 to the substrate 70, the place under the connection portion 62 is filled with the conductive material to form the thinner second conductive portion 121b. Alternatively, by adjusting the width of the connection portion 62 of the mask 6, the thickness of the second conductive portion 722 is accordingly adjusted. If the connection portion 62 is wider, the second conductive portion 722 is thinner, vice versa. It is noted that the electronic device 7 may be varied with other manners. For example, the electronic device 7a in FIG. 2A may be an antenna, and its active area A is the radiation area of the antenna; the electronic device 7b in FIG. 2B may be a FPC (flexible printed circuit); or the electronic device 7c in FIG. 2C is a circuit substrate for carrying IC (IC is not shown) on which a RDL (Redistribution Layer, RDL) or a circuit layer of wafer-level package substrate is disposed.

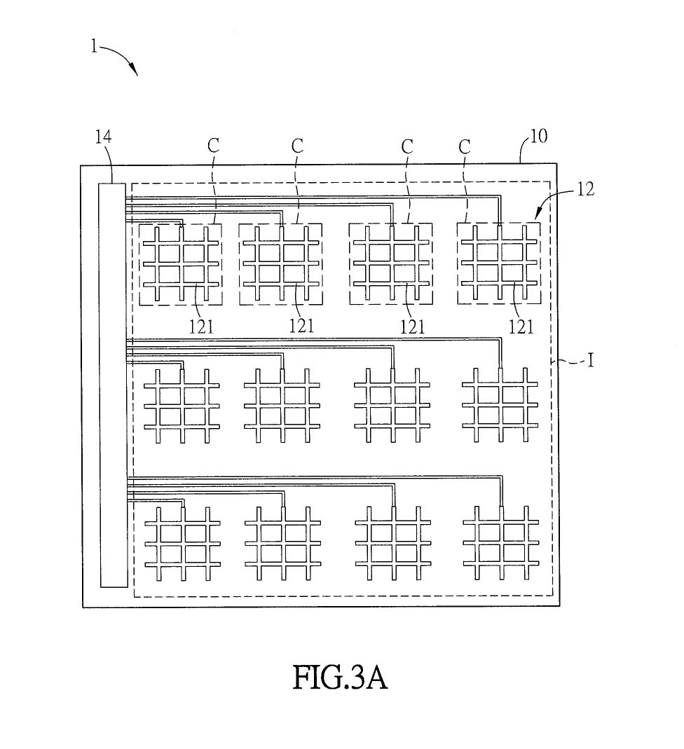

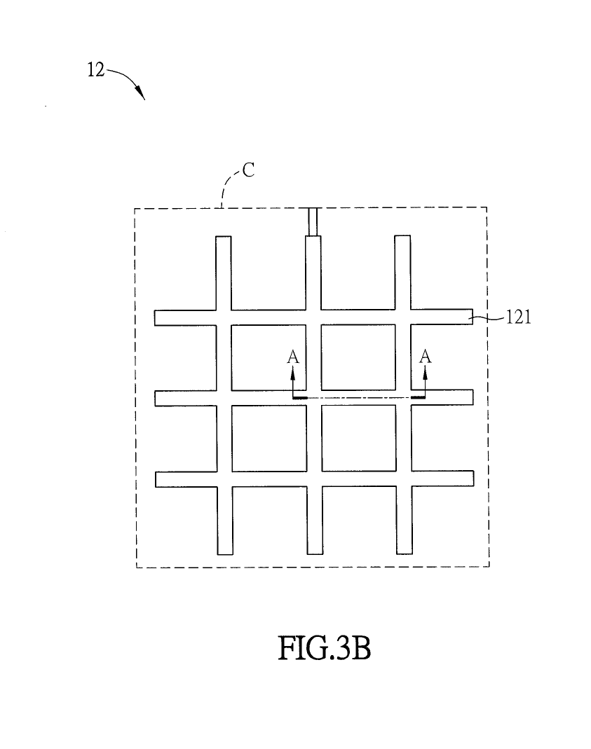

Then, an electronic device according to a second embodiment is illustrated. Referring to FIG. 3A and FIG. 3B, FIG. 3A is a schematic diagram of an electronic device according to a second embodiment. In the embodiment, the electronic device 1 is a sensing panel and includes a detection area I. In the embodiment, the detection area I is referred to as the active area A in the previous embodiment. The detection area I receives a user instruction when the user manipulates the electronic device 1. Its size and location is not restricted. For example, the detection area I may be the display region of the electronic device 1, or the region of user interface. By sensing variations of light, capacitance or resistance, a user action, a gesture or a touch position can be detected for motion sensing, gesture sensing or touch sensing.

Referring to FIG. 3A and FIG. 3B, the first patterned circuit layer 12 includes at least one first metal grid structure 121. At least one part of the first patterned circuit layer 12 is disposed within the detection area I. In the embodiment, the first patterned circuit layer 12 includes a plurality of the first metal grid structures 121, and all the first metal grid structures 121 are disposed within the detection area I for example but not limited. The first metal grid structure 121 in the embodiment is not a grid structure with single thickness, and it will be descripted later.

Moreover, in the embodiment, the first patterned circuit layer 12 further comprises a plurality of first conductive units C. At least one of the first conductive units C comprises the first metal grid structure 121. The first conductive units C may be arranged in an array. In the embodiment, the first conductive units C are arranged in a two dimensional array, but they may be arranged in a honeycomb array, too.

In the embodiment, the first metal grid structures 121 respectively form a plurality of orthogonal metal net structures. In the embodiment, the metal net structures have intersection or they are distributed like a branch. For example, they are an orthogonal grid, a tree structure, a pattern with geometric interlacements or random-distributed elements. In addition to the orthogonal grid in FIG. 3B, the element shape can be a triangle, a diamond, a circle, an ellipse or other polygon.

In the embodiment, the linewidth of the first metal grid structure 121 is between 1 μm to 5 μm and its sheet resistance is below 10Ω/□. The linewidth and the sheet resistance may vary depending on different material and manufacturing process, so they are not limited thereto. The first metal grid structure 121 may be an opaque structure, and the first metal grid structure 121 only occupies 10%˜20% area of the whole first conductive unit C. In other words, the hollowed portion occupies 90%˜98% area of the first conductive unit C to control the transmittance of the detection area I at a preferred transmittance.

One first conductive unit C is related to one position on the substrate 10. When the first conductive unit C receives a sensing signal, the sensing signal is sent to a control unit 14. The control unit 14 determines a user action or a detection position according to the position of the first conductive unit C receiving the sensing signal, and accordingly causes the electronic device to generate a responsive action.

The following description will illustrate the structure of the first conductive unit C as well as one implementation of the first metal grid structure 121. Besides, the mask 2 for manufacturing the first conductive unit C is also illustrated.

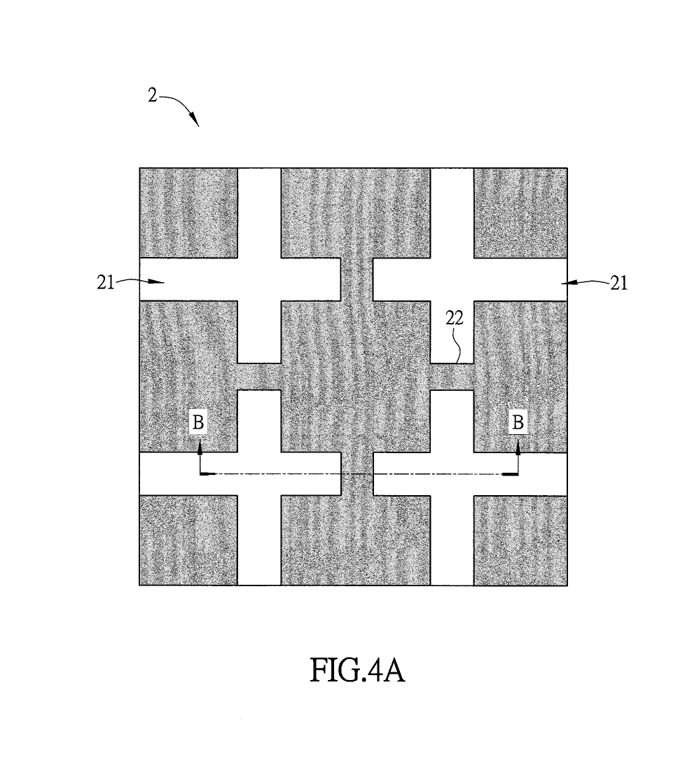

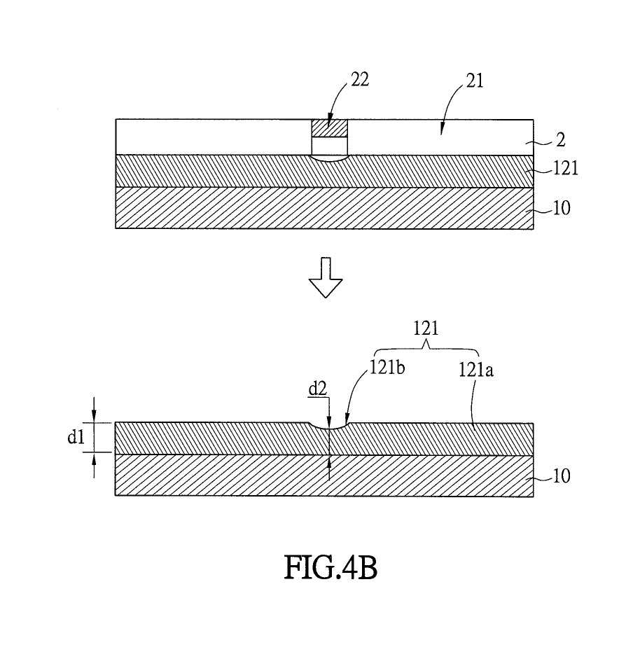

Then, referring to FIG. 3A to FIG. 6, FIG. 4A is a partial enlarged diagram of the mask for manufacturing the device in FIG. 3A, and FIG. 4B is a schematic diagram showing the mask and the patterned circuit layer of the electronic device in FIG. 3A in manufacturing process.

The first conductive unit C comprises the first metal grid structure 121, but the first metal grid structure 121 is not a grid structure with single thickness. FIG. 4B shows the first metal grid structure 121 along the sectional line AA in FIG. 3B. The first metal grid structure 121 may further comprises a plurality of first conductive portions 121a and a plurality of second conductive portions 121b. The material of the first conductive portion 121 a may be the same with the material of the second conductive portion 121b. However, the thickness of the first conductive portion 121a is not equal to the thickness of the second conductive portion 121b. The second conductive portion 121b is connected to the adjacent first conductive portions 121a to form the first metal grid structure 121 in FIG. 3B. The thickness of the first conductive portion 121a is denoted by the first thickness d1, and the thickness of the second conductive portion 121b is denoted by the second thickness d2. The second thickness d2 is smaller than the first thickness d1. In the embodiment, the second thickness d2 is 30%-95% of the first thickness d1. Preferably, by designing the connection portion of the mask 2 (FIG. 4A), the difference between the first thickness d1 and the second thickness d2 is adjusted. For example, increasing the density of the second conductive portion 121b results in that the first metal grid structure 121 has more uniform thickness and better conductibility.

Referring to FIG. 4A, FIG. 4A is a partial enlarged diagram of the mask 2 for manufacturing the first conductive unit C. The mask 2 includes a plurality of hollow portions 21 and connection portions 22. The connection portions 22 can act as ribs for enhancing the structure strength of the mask 2, and help using the mask 2. The material of the mask 2 is for example but not limited to Ni—Fe alloy and it may be a multiple layer structure. Referring to FIG. 4B, it is a sectional diagram along line BB in FIG. 4A. In the manufacturing process, the mask 2 may be disposed very close to the substrate 10. Conductive material for sputtering may be deposited on the substrate 10 by the mask 2, so the first patterned circuit layer 12 is formed on the substrate 10 which includes the first metal grid structure 121. The first metal grid structure 121 is consisted of a plurality of the first conductive units C. The thicker first conductive portion 121a is formed at the place corresponding to the hollow portion 21 of the mask 2. When the conductive material is deposited from the hollow portion 21 to the substrate 10, the place under the connection portion 22 is filled with the conductive material (the conductive material will be inserted toward both sides) to form the thinner second conductive portion 121b. Alternatively, by adjusting the width of the connection portion 22, the thickness of the second conductive portion 121b is accordingly adjusted. If the connection portion 22 is wider, the second conductive portion 121b is thinner, vice versa.

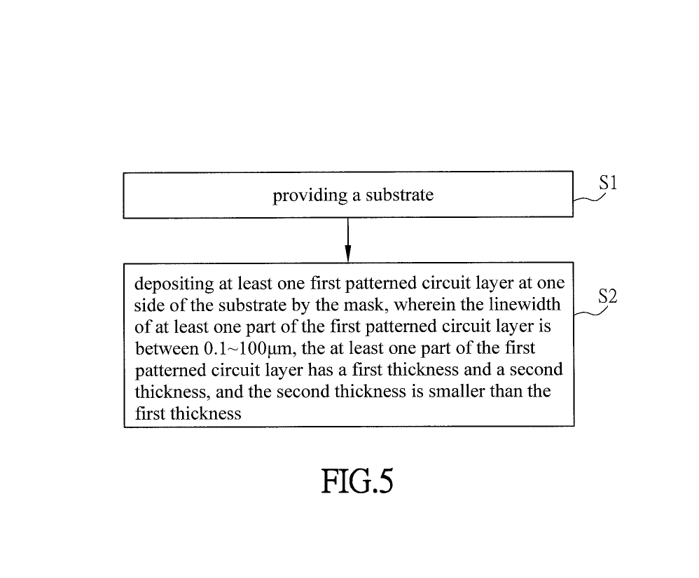

Referring to FIG. 3A to FIG. 4B and FIG. 5, FIG. 5 is a flow chart showing the steps of the method of manufacturing electronic device. The electronic device 1 in FIG. 3A may for example but not limited to be made according to the manufacturing method of FIG. 5.

The method of manufacturing electronic device according to the embodiment at least comprises the following steps of: providing a substrate 10 (step S1); depositing at least one first patterned circuit layer 12 at one side of the substrate 10 by the mask 2, wherein the linewidth of at least one part of the first patterned circuit layer 12 is between 0.1˜100 μm, the at least one part of the first patterned circuit layer 12 has a first thickness d1 and a second thickness d2, and the second thickness d2 is smaller than the first thickness d1 (step S2).

Deposition manner includes for example but not limited to evaporation, sputter, spray, inkjet, printing, coating, PVD, CVD, etc. By the mask 2, the first metal grid structure 121 having the first thickness d1 and the second thickness d2 is formed on the substrate 10. The first metal grid structure 121 is for example but not limited to ITO (indium-tin oxide), IZO (indium-zinc oxide), metal, graphene or other conductive material. In the embodiment, because the first metal grid structure 121 is a grid structure, its transmittance is similar to that of the conventional transparent conductive unit, and the metal material is not limited to ITO (transparent material). Therefore, the required amount of metal and overall cost can be reduced.

In addition to the mask 2 in FIG. 4A, the first conductive unit C may be manufactured by the following mask.

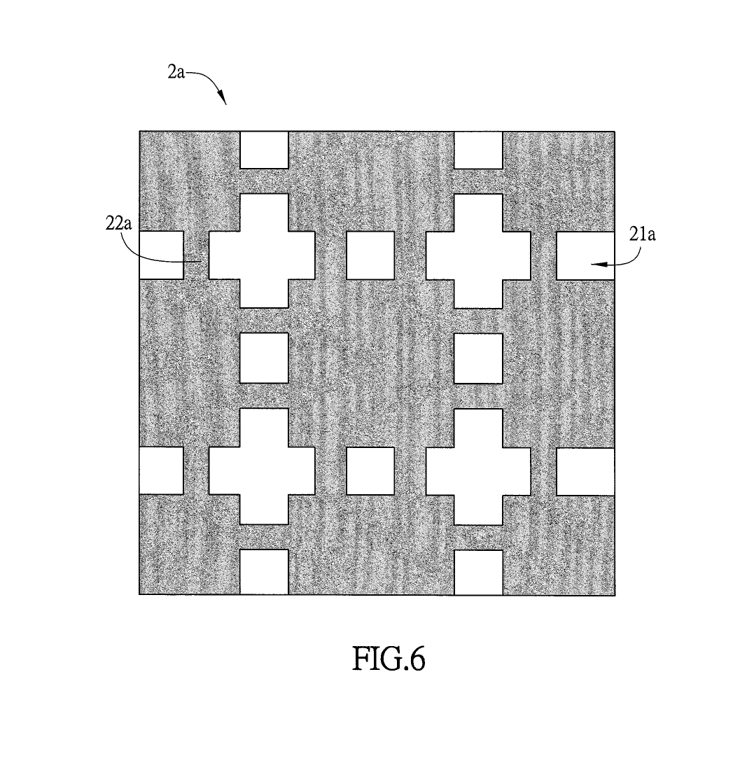

Then, referring to FIG. 6 to FIG. 8, they are schematic diagrams showing different masks for forming the first metal grid structure 121 in FIG. 3A.

FIG. 6 is a partial enlarged diagram of another mask for manufacturing electronic device. The difference from the mask 2 in FIG. 4A is that the hollow portion 21a and the connection portion 22a of the mask 2a in FIG. 6 have similar ratios. Compared with the mask 2, the hollow portions 21a of the mask 2a occupy relatively small area in the whole, and there are more the connection portions 22a. Thus, the number of the second conductive portion of the first metal grid structure in the embodiment will be more than the number of the second conductive portions 121b of the first metal grid structure 121. Compared with the mask of the previous one embodiment, the mask 2a in the embodiment comprises more ribs for enhancing the structure strength of the mask 2a (more the connection portions 22a). Therefore, the mask 2a has better strength and lifetime.

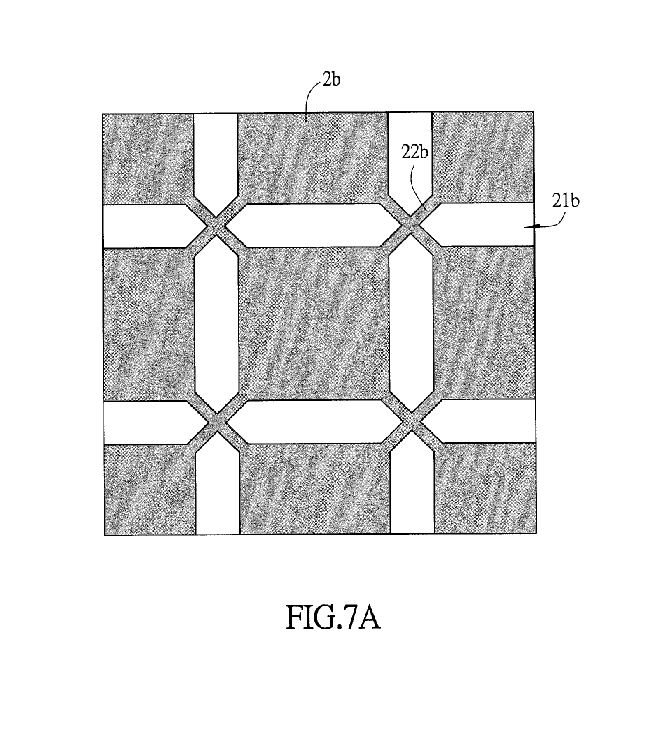

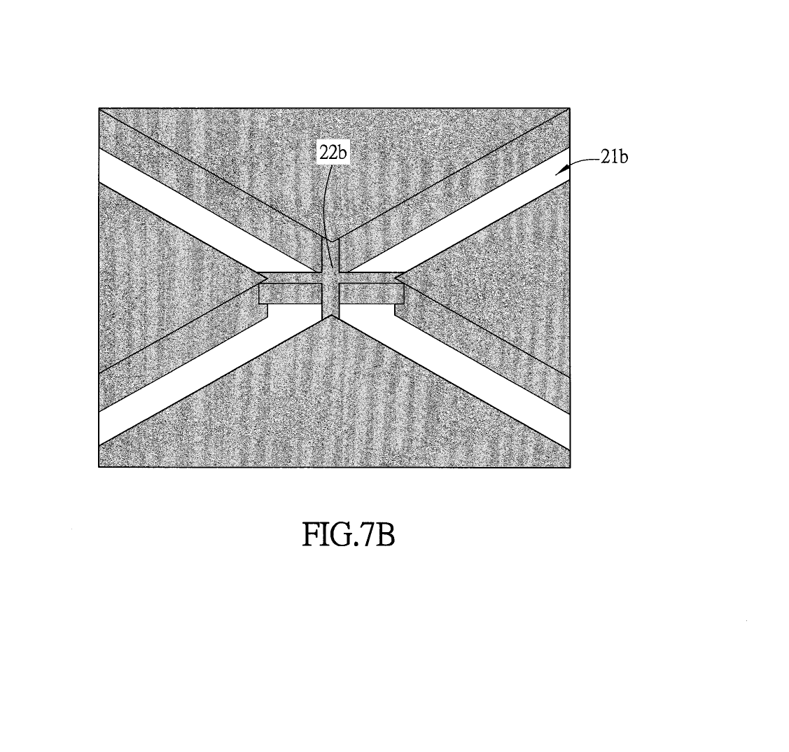

Referring to FIG. 7A and FIG. 7B, FIG. 7A is a partial enlarged diagram of another mask for manufacturing electronic device. FIG. 7B is a perspective diagram of the mask in FIG. 7A. Similarly, in the embodiment, the mask 2b comprises the hollow portions 21b and the connection portions 22b. The thickness of the connection portion 22b is smaller than the average thickness of the mask 2b (excluding the hollow portion 21b). The difference from the previous mask is that the connection portion 22b of the mask 2b in the embodiment is like a crisscross. If the mask 2b is twisted in operation, the crisscross can absorb some stress to avoid the deformation of the mask 2b. The thickness of the connection portion 22b is thinner than the mask 2b, so in the manufacturing process, the connection portion 22b is not directly attached to the substrate and the conductive material can be deposited under the connection portion 22b.

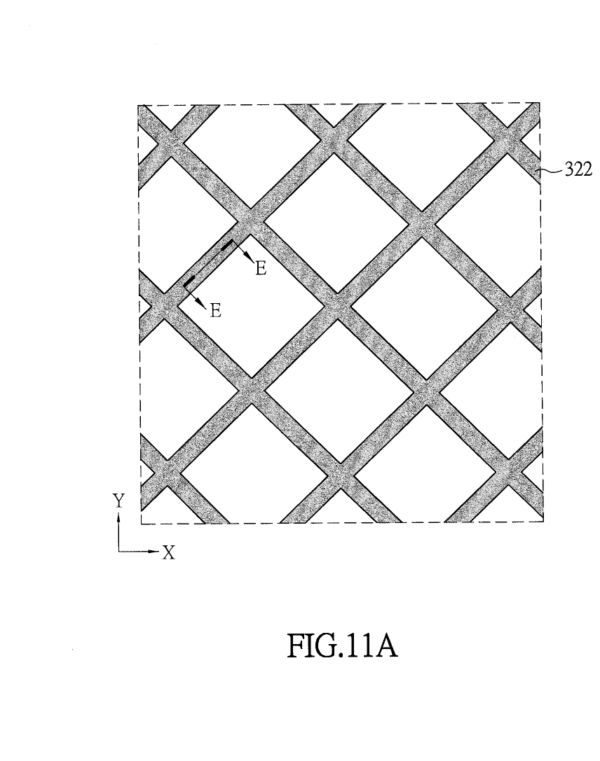

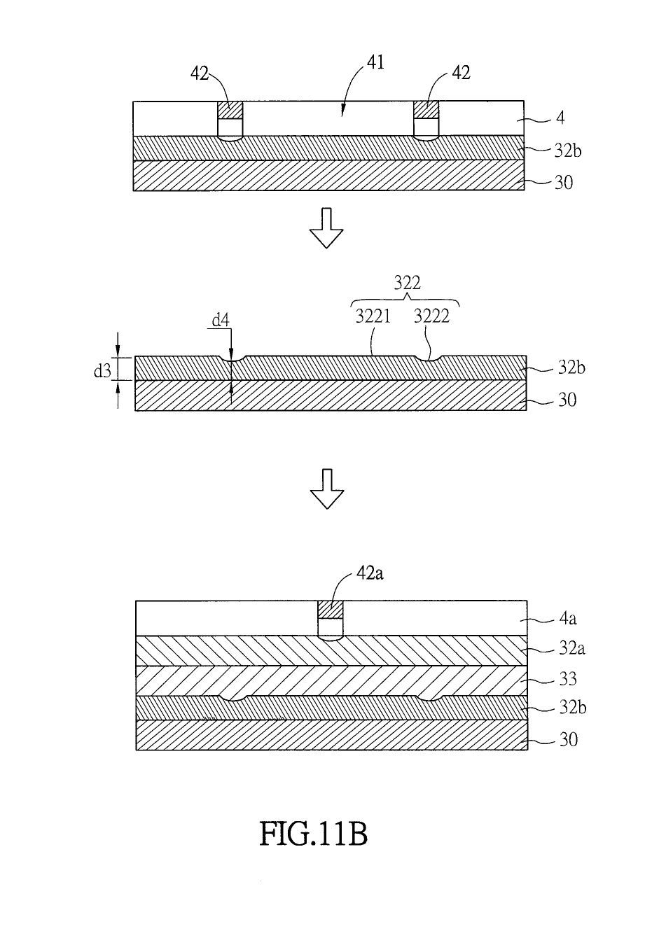

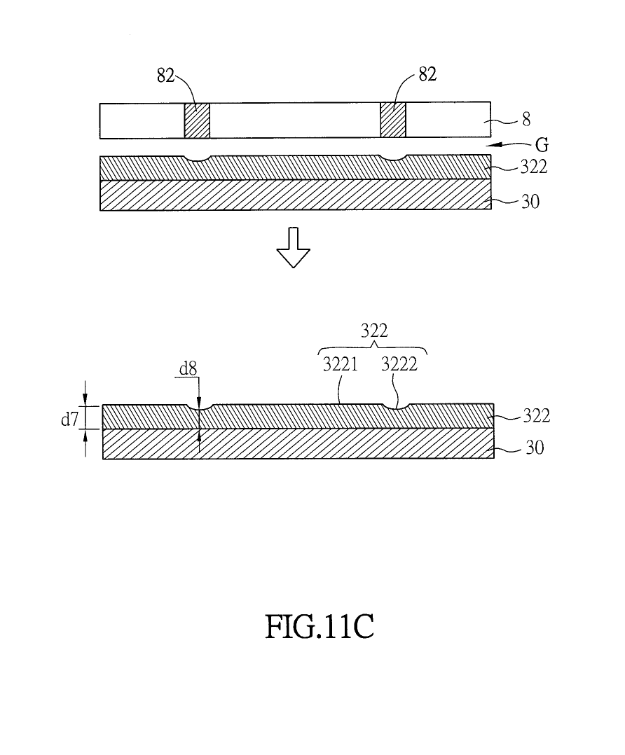

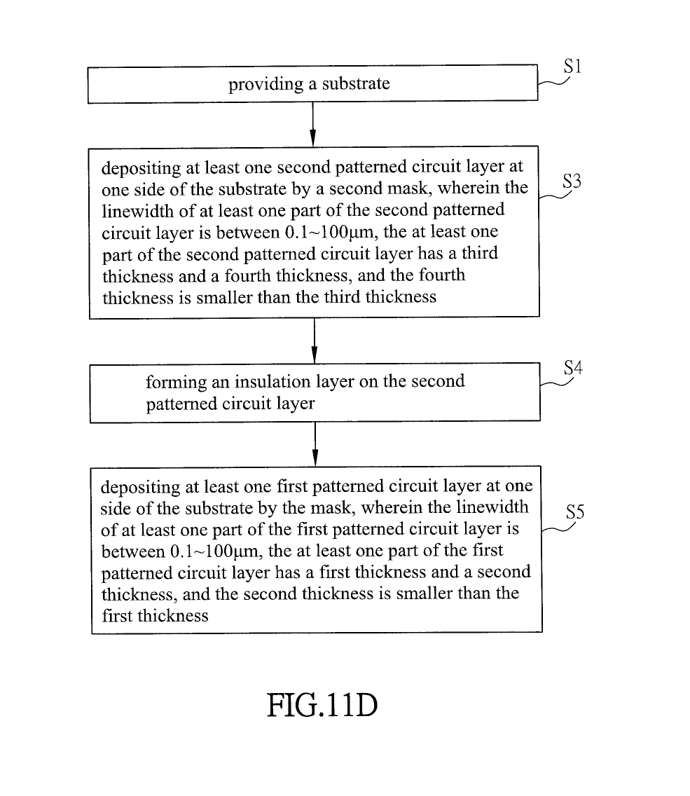

Referring to FIG. 11C, in one variation of the mask, the connection portion 82 and the mask 8 have the same thickness. But the mask 8 is not disposed very close to the substrate 30. A gap G is between the mask 8 and the substrate 30. The conductive material can be deposited on the substrate 30 by the mask 8 to form the second metal grid structure 322 on the substrate 30. The same manufacturing method can be applied to other devices, too.

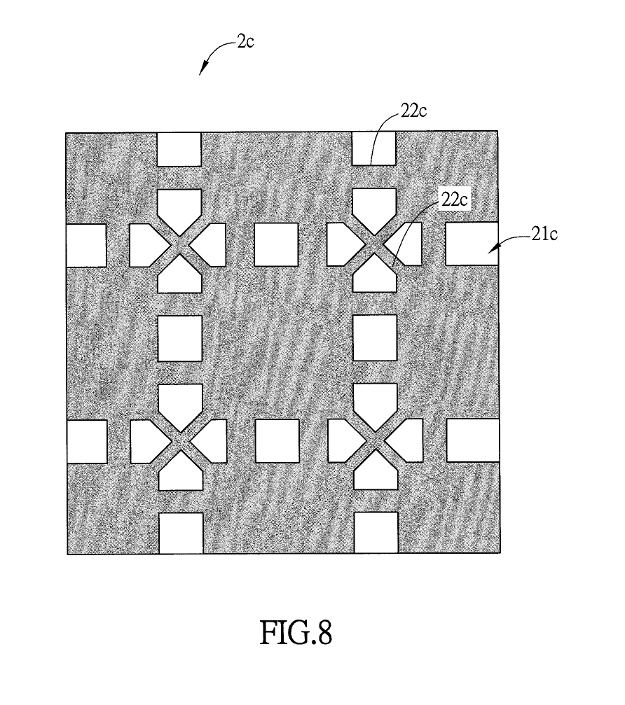

FIG. 8 is another partial enlarged diagram of the mask for manufacturing electronic device. Similarly, in the embodiment, the mask 2c comprises the hollow portions 21c and the connection portions 22c. Furthermore, the mask 2c is FIG. 8 integrates the masks in FIG. 6 and FIG. 7. Thus, the mask in FIG. 8 has the advantages of the masks in FIG. 6 and FIG. 7. Moreover, in the embodiment, not only the number of the ribs for enhancing the structure strength of the mask 2c is increased (more the connection portion 22c), but also the connection portion 22c is like a crisscross to enhance the overall structure strength of the mask 2c. Thus, the mask 2c has better durability and lifetime.

The following description will illustrate the electronic device with double patterned circuit layers according to the second embodiment.

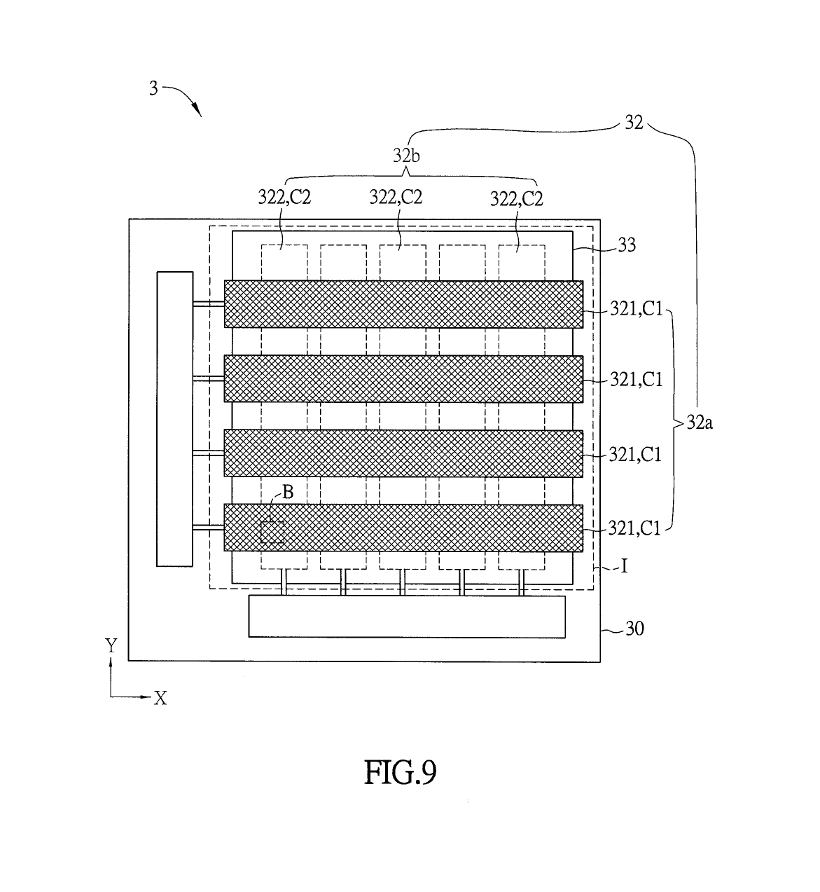

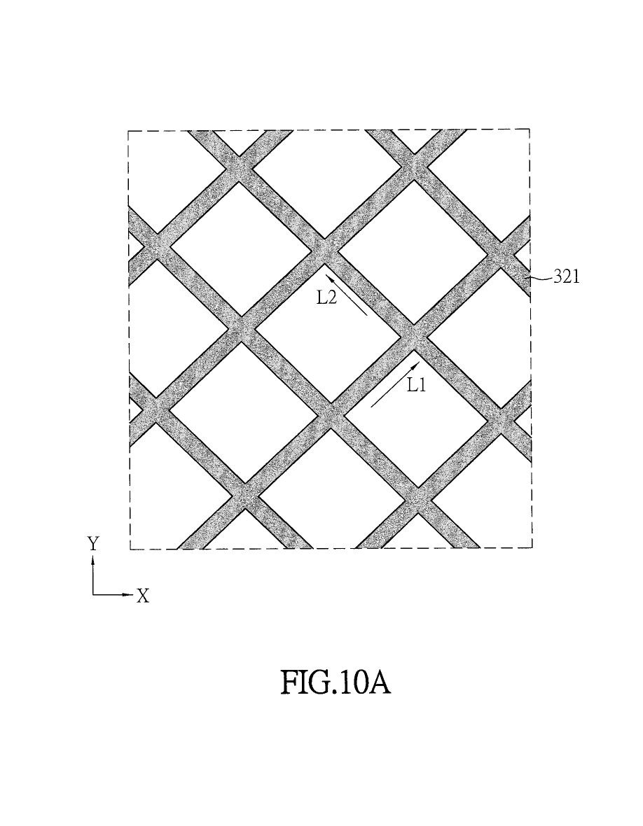

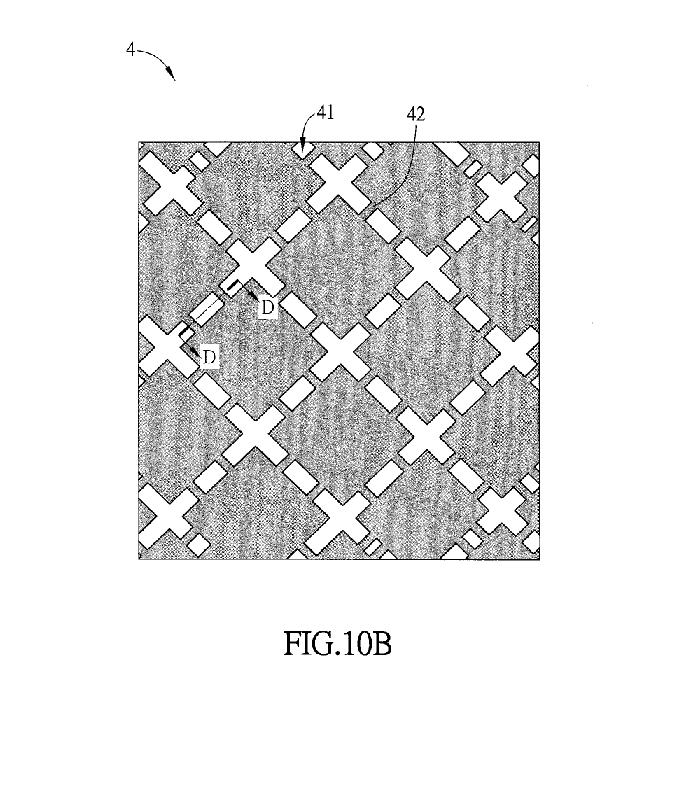

Referring to FIG. 9 and FIG. 10A, FIG. 9 is a schematic diagram of an electronic device according to a second embodiment, and FIG. 10A is a partial enlarged diagram of the dashed-line zone B in FIG. 9.

In the embodiment, the electronic device 3 comprises a first patterned circuit layer 32a, an insulation layer 33 and a second patterned circuit layer 32b. The first patterned circuit layer 32a and the second patterned circuit layer 32b respectively comprise at least one first metal grid structure 321 and at least one second metal grid structure 322. The first metal grid structure 321 and the second metal grid structure 322 may be disposed within the detection area I. FIG. 9 merely shows the first metal grid structure 321 and omits the second metal grid structure 322, but the skilled person in the art should understand the possible the grid structure of relevant embodiment. The first metal grid structure 321 and the second metal grid structure 322 may have the same or different grid structures, and they are not limited to be the same.

In the embodiment, the first metal grid structure 321 comprises a plurality of first conductive units C1, and the second metal grid structure 322 comprises a plurality of second conductive units C2. The first conductive units C1 are arranged in the first axis direction (X axis) in sequence. The second conductive units C2 are arranged in the second axis direction (Y axis) in sequence. The first axis direction (X axis) and the second axis direction (Y axis) are perpendicular to each other for example. In other embodiment, the first axis direction and the second axis direction may be cross each other at an angle. Moreover, the first conductive units Cl and the second conductive units C2 are conductive units in stripe for example metal lines or metal net.

In the embodiment, the electronic device further comprises an insulation layer 33. The insulation layer 33 is disposed between the first patterned circuit layer 32a and the second patterned circuit layer 32b. In the embodiment, the insulation layer 33 is for example but not limited to SiO2, and it is disposed by for example but not limited to deposition, printing, ink-jetting. Preferably, in the embodiment, the insulation layer 33 is formed by printing between the first metal grid structure 321 and the second metal grid structure 322 to electrically insulate the first conductive unit C1 from the second conductive unit C2.

Referring to FIG. 10A, the first metal grid structure 321 defines at least one major axis direction L1, and an included angle is formed between the major axis direction L1 and the first axis direction (X-axis in FIG. 9). The second metal grid structure 322 defines a major axis direction L2, and an included angle is formed between the major axis direction L2 and the second axis direction (Y axis in FIG. 9). In the embodiment, some parts of the first metal grid structure 321 and the second metal grid structure 322 are not parallel to the first axis direction (X axis) and the second axis direction (Y axis).

Then, referring to FIG. 10A, FIG. 10B, FIG. 11A, FIG. 11B and FIG. 11C, the manufacture of the first metal grid structure 321 and the second metal grid structure 322 and the mask thereof in the embodiment are illustrated.

FIG. 10B is a partial enlarged diagram of the mask for manufacturing the device in FIG. 9. FIG. 11A is a schematic diagram of the second patterned circuit layer of the electronic device in FIG. 9. FIG. 11B is a schematic diagram showing the mask and the patterned circuit layer in manufacturing process of the electronic device in FIG. 9, and it is a sectional diagram showing the mask along the sectional line DD in FIG. 10B and a sectional diagram showing the second patterned circuit layer 32b along the sectional line EE in FIG. 11A.

The mask 4 includes a plurality of hollow portions 41 and connection portions 42. The shape of the hollow portion 41 is similar to the shape of the second patterned circuit layer. Similarly to the mask 2, the mask 4 may be composed of Ni—Fe alloy. In manufacturing process, the mask 4 may be disposed very close to the substrate 30. Conductive material is deposited on the substrate 30 by the mask 4, so a plurality of the second conductive units C2 composed of the second metal grid structures 322 are formed on the substrate 30 (FIG. 9). The second metal grid structure 322 includes a plurality of third conductive portions 3221 and a plurality of fourth conductive portions 3222. At least one of the fourth conductive portions 3222 is connected to the adjacent third conductive portion 3221. In the embodiment, the thickness of the third conductive portion 3221 is denoted by the third thickness d3, and the thickness of the fourth conductive portion 3222 is denoted by the fourth thickness d4. The fourth thickness d4 is smaller than the third thickness d3.

The thicker third conductive portion 3221 is formed at the place corresponding to the hollow portion 41 of the mask 4. When the conductive material is deposited from the hollow portion 41 to the substrate 30, the place under the connection portion 42 is filled with the conductive material to form the thinner fourth conductive portion 3222 as shown in FIG. 11B.

Referring to FIG. 11C, it is a flow chart showing the steps of the manufacturing method electronic device according to a second embodiment.

The method of manufacturing electronic device at least comprises the steps of: providing a substrate (step S1); and depositing at least one second patterned circuit layer 32b at one side of the substrate 30 by a second mask 4a, wherein the linewidth of at least one part of the second patterned circuit layer 32b is between 0.1˜100 μm, the at least one part of the second patterned circuit layer 32b has a third thickness and a fourth thickness, and the fourth thickness is smaller than the third thickness (step S3).

In the embodiment, the method further comprises: forming an insulation layer 33 on the second patterned circuit layer 32b (step S4); depositing at least one first patterned circuit layer 32a at one side of the substrate by the mask 4, wherein the linewidth of at least one part of the first patterned circuit layer 32a is between 0.1˜100 μm, the at least one part of the first patterned circuit layer 32a has a first thickness and a second thickness, and the second thickness is smaller than the first thickness (step S5). The first patterned circuit layer 32a is formed on the insulation layer 33. Because step S5 is similar to step S2 in second embodiment, it is not repeated here.

Although different masks are utilized for the first patterned circuit layer 32a and the second patterned circuit layer 32b, in the embodiment, the same mask can be utilized for the first patterned circuit layer 32a and the second patterned circuit layer 32b. In the case of the same mask, when the first patterned circuit layer 32a has been formed, the mask 4 is rotated to form stripe conductive structures arranged in the first axis direction (X axis) in sequence.

Then, in the third embodiment, the first patterned circuit layer may comprise two conductive units at the same layer but in different axis directions. It is different from the previous embodiment which has two patterned sensing electrode layer respectively forming two conductive units.

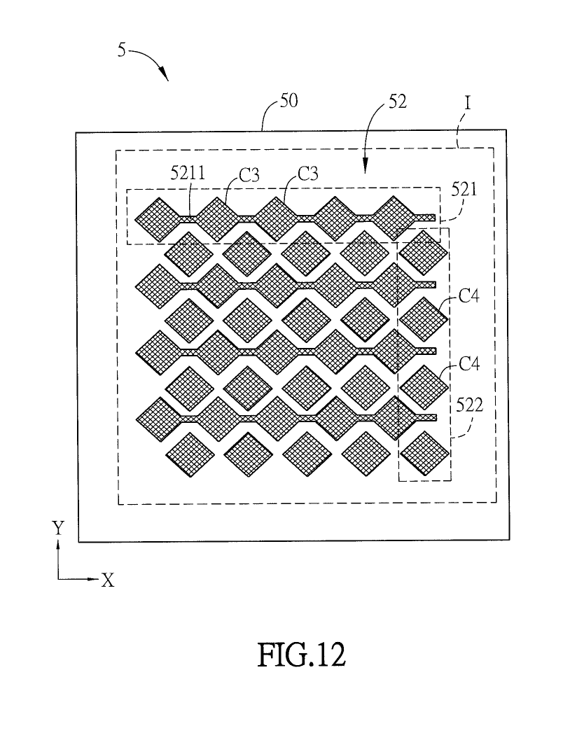

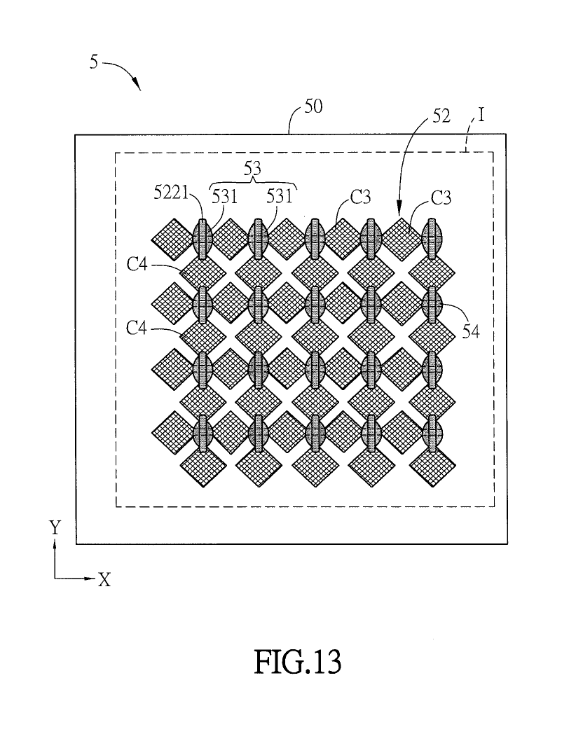

Referring to FIG. 12 to FIG. 13, FIG. 12 is a schematic diagram showing the intermediate structure in manufacturing process of the electronic device according to the second embodiment, and FIG. 13 is a schematic diagram of the patterned circuit layer of the electronic device according to the second embodiment.

In the embodiment, the electronic device 5 comprises a substrate 50 and a first patterned circuit layer 52. The first patterned circuit layer 52 is disposed at one side of the substrate 50. In the embodiment, the first patterned circuit layer 52 is disposed above the substrate 50 for example.

The first patterned circuit layer 52 includes the first metal grid structures 521, 522. At least one part of the first patterned circuit layer 52 is disposed within the detection area I. Similarly, in the embodiment, the first patterned circuit layer 52 comprises at least one first metal grid structure 521 and at least one first metal grid structure 522. Similarly, the first metal grid structures 521, 522 are the same with the previous first metal grid structure, they have a first thickness and a second thickness, and the second thickness is smaller than the first thickness. Because the first metal grid structures 521, 522 can refer to the above related description, they are not repeated here.

Furthermore, in the embodiment, the first patterned circuit layer 52 further comprises a plurality of the first conductive units C3 and a plurality of second conductive units C4. The first conductive unit C3 and the second conductive unit C4 are insulated from each other.

In the embodiment, the first conductive units C3 are arranged along the first axis direction (X axis) in sequence, and the second conductive units C4 are arranged along the second axis direction (Y axis) in sequence.

In the embodiment, the first conductive unit C3 includes at least one first electrical connection member 5211 to be electrically connected to the adjacent first conductive unit C3.

Each second conductive unit C4 includes at least one second electrical connection member 5221 to be electrically connected to the adjacent second conductive unit C4 in the first axis direction (X axis). Because the first conductive unit C3 and the second conductive unit C4 are respectively arranged along different axes, the first electrical connection member 5211 of the first conductive unit C3 crisscrosses and the second electrical connection member 5221 of the adjacent second conductive unit C4.

Moreover, in the embodiment, the electronic device 5 further comprises an insulation layer 53. The insulation layer 53 comprises a plurality of insulation members 531 respectively disposed between the first electrical connection members 5211 of the first conductive units C3 and the second electrical connection members 5221 of the second conductive unit C4, so as to electrically insulate the first conductive unit C3 from the second conductive unit C4.

As to the manufacture of the first patterned circuit layer 52 of the electronic device 5, first, conductive material is deposited at one side of the substrate 50 by a first mask (not shown) to form a plurality of first conductive units C3 and a plurality of second conductive units C4.

Then, a plurality of the insulation members 531 are disposed on the first electrical connection member 5211. In the next step, a plurality of the second electrical connection members 5221 are disposed on a plurality of the insulation members 531. The second electrical connection member 5221 A electrically connected to the adjacent second conductive unit C4. In the embodiment, because the insulation member 531 is disposed between the first electrical connection member 5211 and the second electrical connection member 5221, the first conductive unit C3 and the second conductive unit C4 are electrically isolated from each other. In the embodiment, the insulation member 531 may be formed between the first electrical connection member 5211 and the second electrical connection member 5221 by dispensing.

Moreover, the electronic devices in the previous embodiments can be applied to a display device. The display device may comprise a first substrate, a second substrate, a display medium and the first patterned circuit layer mentioned in any one of the previous embodiments. The second substrate is disposed opposite the first substrate and includes the detection area. The area of the detection area may be smaller than, equal to or greater than the area of a display region of the display device. The display medium is disposed between the first substrate and the second substrate. The situation where the first patterned circuit layer is disposed at one side of the second substrate includes: the first patterned circuit layer is disposed on the second substrate; and the first patterned circuit layer is disposed on another substrate but still at one side of the second substrate.

The display medium includes for example but not limited to liquid crystal material, plasma material, electrophoresis material, OLED material or LED material. Preferably, it is liquid crystal material.

Depending on the type of the display device, the first patterned circuit layer can be disposed on the side of the second substrate facing the display medium, or it can be disposed on the side of the second substrate away from the first substrate.

Moreover, the first patterned circuit layer may be disposed corresponding to the black matrix of the second substrate, so the first patterned circuit layer does not additionally decrease transmittance (by using the original shading zone of the black matrix). Therefore, even the material of the first patterned circuit layer is not transparent metal, the shading rate is not decreased.

In summary, the patterned circuit layer is disposed on the substrate by depositing with mask. This manufacturing process is simple and can replace lithography process of multiple steps so as to decrease the manufacturing steps. In the embodiment, metal grid structures have similar transmittance to the conventional transparent circuit, and the designate material of transparent metal oxide is not required. The overall required amount of metal and cost can be reduced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An electronic device, comprising:
a substrate; and
a first patterned circuit layer, disposed at one side of the substrate, wherein the linewidth of at least one part of the first patterned circuit layer is between 0.1˜100 μm, the at least one part of the first patterned circuit layer has a first thickness and a second thickness, and the second thickness is smaller than the first thickness.

2. The electronic device of claim 1, including an active area where the first patterned circuit layer has the first thickness and the second thickness.

3. The electronic device of claim 2, where the active area is a radiation area of an antenna, a visible area of a display panel, or a detection area of a touch panel.

4. The electronic device of claim 1, wherein the first patterned circuit layer includes a grid structure.

5. The electronic device of claim 1, wherein the first patterned circuit layer further comprises a plurality of first conductive units, at least one of the first conductive units includes the first metal grid structure, and the first metal grid structure includes a plurality of first conductive portions and a plurality of second conductive portions, at least one of the first conductive portions is connected to the adjacent second conductive portions, the thickness of the at least one of the first conductive portions is denoted by the first thickness, and the thickness of the at least one of the second conductive portions is denoted by the second thickness.

6. The electronic device of claim 5, wherein the first conductive units are arranged in an array.

7. The electronic device of claim 5, wherein the first patterned circuit layer further comprises a plurality of second conductive units, at least one of the second conductive units comprises another first metal grid structure, wherein the first conductive units are arranged along a first axis direction in sequence, and the second conductive units are arranged along a second axis direction in sequence.

8. The electronic device of claim 7, wherein each of the first conductive units includes at least one first electrical connection member to be electrically connected to the adjacent first conductive unit, each of the second conductive units includes at least one second electrical connection member to be electrically connected to the adjacent second conductive unit, and the first electrical connection member of the first conductive unit crisscrosses the second electrical connection member of the adjacent second conductive unit.

9. The electronic device of claim 8, further comprising:
an insulation layer, comprising a plurality of insulation members respectively disposed between the first electrical connection member of each of the first conductive units and the second electrical connection member of each of the second conductive units to electrically isolate the first conductive units from the second conductive units.

10. The electronic device of claim 1, further comprising:
an insulation layer; and
a second patterned circuit layer, wherein the first patterned circuit layer is disposed on the insulation layer, the insulation layer is disposed on the second patterned circuit layer, the second patterned circuit layer comprises at least one second metal grid structure, wherein within the detection area, the second metal grid structure has a third thickness and a fourth thickness, and the fourth thickness is smaller than the third thickness.

11. The electronic device of claim 10, wherein the first patterned circuit layer further comprises a plurality of first conductive units, the second patterned circuit layer further comprises a plurality of second conductive units, at least one of the second conductive units comprises the second metal grid structure, the second metal grid structure includes a plurality of third conductive portions and a plurality of the fourth conductive portions, at least one of the third conductive portions is connected to the adjacent fourth conductive portions, the thickness of the at least one of the third conductive portions is denoted by the third thickness, and the thickness of the at least one of the fourth conductive portions is denoted by the fourth thickness.

12. The electronic device of claim 1, wherein the electronic device is a touch display device, a touch panel, a circuit board, or an antenna.

13. A method of manufacturing an electronic device including a detection area, comprising:
providing a substrate; and
depositing at least one first patterned circuit layer at one side of the substrate by a first mask, wherein the linewidth of at least one part of the first patterned circuit layer is between 0.1˜100 μm, the at least one part of the first patterned circuit layer has a first thickness and a second thickness, and the second thickness is smaller than the first thickness.

14. The method of claim 13, wherein the at least one first patterned circuit layer is deposited by sputtering.

15. The method of claim 13, wherein the electronic device includes an active area, and the at least one first patterned circuit layer is deposited by the first mask within the active area.

16. The method of claim 13, further comprising:
forming a second patterned circuit layer by a second mask, wherein the second patterned circuit layer has a third thickness and a fourth thickness, and the fourth thickness is smaller than the third thickness; and
forming an insulation layer on the second patterned circuit layer, wherein the first patterned circuit layer is formed on the insulation layer.

17. The method of claim 16, wherein the electronic device includes an active area, and the second patterned circuit layer is deposited by the second mask within the active area.
